(19) United States
(12) Patent Application Publication
(10) Pub. No.: US 2013/0288485 A1
(43) Pub. Date: Oct. 31, 2013

(54) DENSIFICATION FOR FLOWABLE FILMS

(71) Applicant: APPLIED MATERIALS, INC., Santa Clara, CA (US)

(72) Inventors: Jingmei Liang, San Jose, CA (US); Sukwon Hong, San Jose, CA (US); Jun Tae Choi, Suwon (KR)

(73) Assignee: Applied Materials, Inc., Santa Clara, CA (US)

(21) Appl. No.: 13/792,767

(22) Filed: Mar. 11, 2013

Related U.S. Application Data
(60) Provisional application No. 61/640,514, filed on Apr. 30, 2012.

(51) Int. Cl. H01L 21/02

(52) U.S. Cl. CPC H01L 21/02271; H01L 21/02282
USPC 438/782; 438/778

(57) ABSTRACT

A method of forming a dielectric layer is described. The method first deposits an initially-flowable layer on a substrate. The initially-flowable layer is then densified by exposing the substrate to a high-density plasma (HDP). Essentially no additional material is deposited on the initially-flowable layer, in embodiments, but the impact of the accelerated ionic species serves to condense the layer and increase the etch tolerance of the processed layer.

### CROSS-REFERENCES TO RELATED APPLICATIONS

This application claims the benefit of U.S. Provisional Application No. 61/640,514, filed Apr. 30, 2012, and titled “IMPROVED DENSIFICATION FOR FLOWABLE FILMS,” which is hereby incorporated herein in its entirety for all purposes.

### BACKGROUND OF THE INVENTION

Semiconductor device geometries have dramatically decreased in size since their introduction several decades ago. Modern semiconductor fabrication equipment routinely produce devices with 32 nm, 28 nm and 22 nm feature sizes, and new equipment is being developed and implemented to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam in the middle of the gap.

Over the years, many techniques have been developed to avoid having dielectric material clog the top of a gap, or to “heal” the void or seam that has been formed. One approach has been to start with highly flowable precursor materials that may be applied in a liquid phase to a spinning substrate surface (e.g., SOG deposition techniques). These flowable precursors can flow into and fill very small substrate gaps without forming voids or weak seams. However, once these highly flowable materials are deposited, they have to be hardened into a solid dielectric material.

In many instances, the hardening includes a heat treatment to remove components from the deposited material to leave behind a solid dielectric such as silicon oxide. Some of these components were necessary to make the initially deposited film flowable. Departing components increase the density of the hardened dielectric which, typically and desirably, increases the etch resistance of the hardened film. The hardening dielectric tends to shrink in volume, which can leave cracks and spaces at the interlace of the dielectric and the surrounding substrate.

Spin-on dielectrics (SOD) have also been used to flow into features on a patterned substrate. The material is generally converted to silicon oxide from a silazane-type layer which contains silicon, nitrogen and hydrogen. Silicon, nitrogen and hydrogen containing layers are typically converted to silicon oxide at high temperature in an oxygen containing environment. Oxygen iron from the environment displaces nitrogen and hydrogen to create the silicon oxide layer. High temperature exposure to oxygen environments can ruin underlying layers for some circuit architectures. This consideration results in the need to stay within a “thermal budget” during a manufacturing process flow. Thermal budget considerations have largely limited SOD to process flows incorporating an underlying silicon nitride layer which can protect underlying features from oxidation (e.g. DRAM applications). Alternative methods have been developed which deposit silazane containing layers by radical-component CVD. Radical-component CVD can create a flowable layer by exciting one precursor and combining it with an unexcited silicon-containing precursor in the plasma-free substrate processing region.

The flowability of each of these films may result from distinct chemical components from other flowable films, but densifying the films is almost uniformly desirable across the suite of flowable deposition techniques. Thus, there is a need for new post processing techniques for densifying the wide variety of flowable films envisioned, under development and currently available. This and other needs are addressed in the present application.

### BRIEF SUMMARY OF THE INVENTION

A method of forming a dielectric layer is described. The method first deposits an initially-flowable layer on a substrate. The dielectric layer is flowable during the operation of forming the dielectric layer. The initially-flowable layer is then densified by exposing the substrate to a high-density plasma (HDP). Essentially no additional material is deposited on the initially-flowable layer, in embodiments, but the impact of the accelerated ionic species serves to condense the layer and increase the etch tolerance of the processed layer.

Embodiments of the invention include methods of forming a dielectric layer on a substrate. The methods include the sequential steps of (1) forming a dielectric layer on the substrate, and (2) treating the dielectric layer by exposing the layer to a high density plasma. Step (2) increases a density of the dielectric layer.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps for making a dielectric layer according to embodiments of the invention.

FIG. 2 shows a substrate processing system according to embodiments of the invention.

FIG. 3A shows a film densification chamber according to embodiments of the invention.

FIG. 3B shows a simplified cross section of a gas ring according to embodiments of the invention.

FIG. 4A shows a flowable film deposition chamber according to embodiments of the invention.

FIG. 4B shows a gas introducing showerhead according to embodiments of the invention.

### DETAILED DESCRIPTION OF THE INVENTION

A method of forming a dielectric layer is described. The method first deposits an initially-flowable layer on a substrate. The initially-flowable layer is then densified by exposing the substrate to a high-density plasma (HDP). Essentially no additional material is deposited on the initially-flowable layer, in embodiments, but the impact of the accelerated ionic species serves to condense the layer and increase the etch tolerance of the processed layer.

Post-processing an initially-flowable dielectric layer with a high density plasma has been found to dramatically densify and reduce the wet etch rate of the processed dielectric layer. The flowable layer may be deposited by a process such as spin-on glass (SOG) spin-on dielectric (SOD), an eHARP process (H₂O-TEOS-O₃), SACVD or a flowable CVD process such as radical-component CVD. Flowable films can have a reduced density and elevated etch rate compared to non-flowable films. The high density plasma treatments described herein have been found to enable a dramatic reduction of wet etch rate ratio, for example from 3-5 to well below 3.

As used herein, a high-density-plasma process is a plasma CVD process that employs a plasma having an ion density on the order of 10¹¹ ions/cm³ or greater. A high-density plasma may also have an ionization fraction (ion/neutral ratio) on the order of 10⁻⁴ or greater. Typical HDP-CVD processes are geared towards the gap-fill of trench geometries. In gapfill processes, a substrate bias RF power is used to accelerate ions toward the substrate which produces a narrow range of approach trajectories. This narrowing combined with spattering activity allows gaps to be filled before the top corners of a growing via come together to form and maintain a void. As such, deposition-to-sputter ratios (D:S) are often used to characterize HDP-CVD. However, the current invention strives to deposit little or no additional material and instead strives to compress the material already present on the substrate. A conventional definition of the D:S ratio is:

$$\frac{( net deposition rate ) + ( blanket sputtering rate )}{( blanket sputtering rate )}$$

The deposition-to-sputter ratio increases with increased deposition and decreases with increased sputtering. As used in the definition of the deposition-to-sputter ratio, the “net deposition rate” refers to the deposition rate that is measured when deposition and sputtering are occurring simultaneously. The “blanket sputter rate” is the sputter rate measured when the process recipe is run without deposition gases (leaving nitrogen and a fluent for example). The flow rates of the remaining gases are increased, maintaining fixed ratios among them, to attain the pressure present in the process chamber during normal processing. No or essentially no deposition gases are used in embodiments of the present invention so the D:S ratio may be essentially equal to unity. Another conventional scalar used to quantify traditional HDP processes is called a “etching-to-deposition ratio.” The definition of the etching-to-deposition ratio contains a “source-only deposition rate” in the denominator of the quantity. This quantity exists at or approaches a singularity for the present invention. Therefore, these two canonical ratios will not be referred to extensively in this application and the HDP densification processes described herein may be used with and without application of substrate bias power in embodiments of the invention.

The examples described herein will focus on deposition of a radical-component CVD silazane film, i.e. silicon-nitrogen-and-hydrogen-containing layer and a subsequent high density plasma treatment which has been found to reduce the etch rate of the resulting films. Without the high-density plasma treatment, the etch rate of silicon oxide films created by radical-component CVD followed by ozone curing and oxygen anneals or water treatments have been found be three to live times faster than thermal oxide layers. The high-density plasma treatment methods taught herein may also have utility radical-component CVD carbon-based films, spin on glass (SOG), spin on dielectric (SOD) as well as other flowably deposited dielectrics. The films may include silicon, hydrogen and nitrogen in embodiments. The films may include silicon, carbon, oxygen, hydrogen and nitrogen in embodiments of the invention. Additional details about the methods and systems of forming the silicon oxide capping layer will now be described.

### An Exemplary Dielectric Stack Process

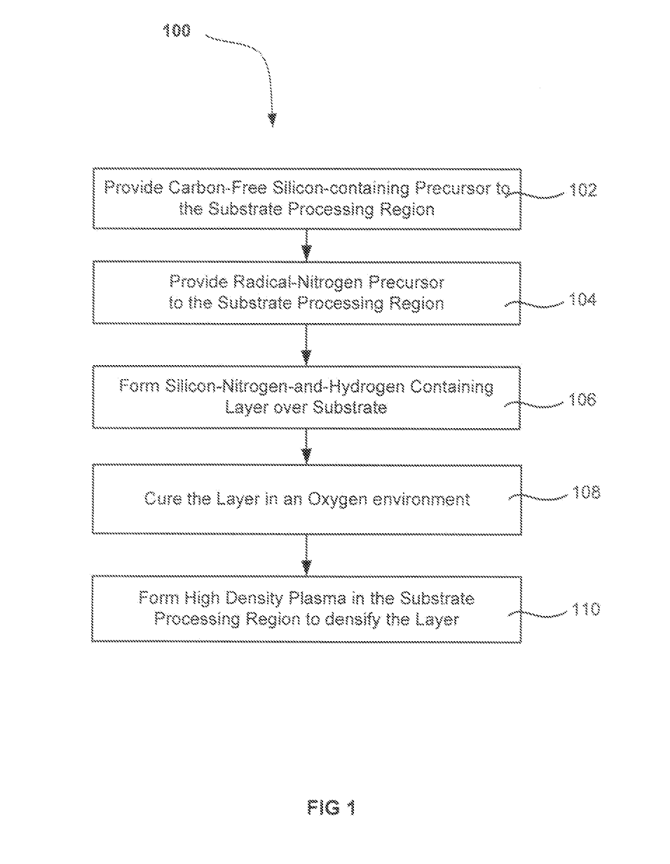

FIG. 1 is a flowchart showing selected steps in a method 100 of making a dielectric stack of layers according to embodiments of the invention. The method 100 includes providing a carbon-free silicon-containing precursor to a substrate processing region 102. The carbon-free silicon-containing precursor does not pass through a plasma excitation, in embodiments, so the precursor travels into the substrate processing region intact. Excitation is then provided only by the radical precursor to be described shortly. The carbon-free silicon-containing precursor may be, for example, a silicon-and-nitrogen-containing precursor, a silicon-and-hydrogen-containing precursor, or a silicon-nitrogen-and-hydrogen-containing precursor, among other classes of silicon precursors. The absence of carbon reduces the shrinkage of the deposited layer. The silicon-containing precursor may be oxygen-free in addition to carbon-free in some embodiments of the invention. A lack of oxygen results in a lower concentration of silanol (Si—OH) groups in the silicon-and-nitrogen-containing layer formed from the precursors. Excess silanol moieties in the deposited layer can cause increased porosity and shrinkage during post deposition steps that remove the hydroxy (—OH) moieties from the deposited layer.

Specific examples of carbon-free silicon precursors may include silyl-amines such as H₂N(SiH₃), HN(SiH₃)₂, and N(SiH₃)₃, among other silyl-amines. The flow rates of a silyl-amine may be greater than or about 200 sccm, greater than or about 300 sccm or greater than or about 500 sccm in different embodiments. All flow rates given herein refer to a dual chamber substrate processing system. Single wafer systems would require half these flow rates and other water shapes/sizes would require flow rates sealed by the processed area. These silyl-amines may be mixed with additional gases that may act as carrier gases, reactive gases, or both. Additional gases may include H₂, N₂, NH₃, He, Ne and/or Ar, among other gases. Examples of carbon-free silicon-containing precursors may also include silane (SiH₄) either alone or mixed with other silicon (e.g., N(SiH₃)₃), hydrogen (e.g., H₂), and/or nitrogen (e.g., N₂, NH₃) containing gases. Carbon-free silicon-containing precursors may also include disilane, trisilane, even higher-order silanes, and chlorinated silanes, alone or in combination with one another or the previously mentioned carbon-free silicon-containing precursors.

A radical precursor is also provided to the substrate processing region 104. A radical precursor describes plasma effluents produced in the plasma excitation outside the substrate processing region from any stable species (inert or reactive). The radical precursor may be a nitrogen-containing radical precursor which will be referred to herein as a radical-nitrogen precursor. The radical-nitrogen precursor is a nitrogen-radical-containing precursor that was generated outside the substrate processing region from a more stable nitrogen precursor. A stable precursor may be referred to herein as an unexcited precursor to indicate that the precursor has not yet passed through a plasma. A stable nitrogen precursor compound containing NH₃, hydrazine (N₂H₄) and/or N₂ may be activated in a chamber plasma region or another remote plasma system (RPS) outside the processing chamber to form the radical-nitrogen precursor, which is then transported into the substrate processing region to excite the silicon-containing precursor. The activation of the stable nitrogen precursor into the radical-nitrogen precursor involves dissociation which may be accomplished by means of thermal dissociation, ultraviolet light dissociation, and/or plasma dissociation, among other methods. Plasma dissociation may involve striking a plasma from helium, argon, hydrogen (H₂), xenon, ammonia (NH₃), etc., in a remote plasma generating chamber and introducing the stable nitrogen precursor to the plasma region to generate the radical-nitrogen precursor.

The stable nitrogen precursor may also be a mixture comprising NH₃ & N₂, NH₃ & H₂, NH₃ & N₂ & H₂ and N₂ & H₂, in different embodiments. Hydrazine may also be used in place of or in combination with NH₃ and in the mixtures involving N₂ and H₂. The flow rate of the stable nitrogen precursor may be greater than or about 300 sccm, greater than or about 500 sccm or greater than or about 700 sccm in different embodiments. The radical-nitrogen precursor produced in the chamber plasma region may be one or more of —N, —NH, —NH₂, etc., and may also be accompanied by ionized species formed in the plasma. Sources of oxygen may also be combined with the more stable nitrogen precursor in the remote plasma in embodiments of the invention. The addition of a source of oxygen pre-loads the layer with oxygen while decreasing flowability. Sources of oxygen may include one or more of O₂, H₂O, O₃, H₂O₂, N₂O, NO or NO₂.

In embodiments employing a chamber plasma region, the radical-nitrogen precursor is generated in a section of the substrate processing region partitioned from a deposition region where the precursors mix and react to deposit the silicon-and-nitrogen-containing layer on a deposition substrate (e.g., a semiconductor wafer). The radical-nitrogen precursor may also be accompanied by a carrier gas such as hydrogen (H₂), nitrogen (N₂), helium, neon, argon etc. The substrate processing region may be described herein as “plasma-free” during the growth of the carbon-free silicon-nitrogen-and-hydrogen-containing layer and during subsequent processes. “Plasma-free” does not necessarily mean the region is devoid of plasma. The borders of the plasma in the chamber plasma region are hard to define and may encroach upon the substrate processing region through the apertures in the showerhead. In the case of an inductively-coupled plasma, e.g., a small amount of ionization may be initiated within the substrate processing region. Generally, a low intensity plasma may be created in the substrate processing region without compromising the flowable nature of the forming layer. All causes for a plasma having much lower ion density than the remote/chamber plasma region dining the creation of the radical nitrogen precursor do not deviate from the scope of “plasma-tree” as used herein.

In the substrate processing region, the carbon-free silicon precursor and the radical-nitrogen precursor mix and react to deposit a silicon-nitrogen-and-hydrogen-containing layer on the deposition substrate 106. In embodiments, the deposited silicon-nitrogen-and-hydrogen-containing layer has flowable characteristics unlike conventional silicon nitride (Si₃N₄) layer deposition techniques. The flowable nature during formation allows the layer to flow into narrow matures before solidifying.

Nitrogen in the silicon-nitrogen-and-hydrogen-containing layer may originate from either (or both) of the radical precursor or the unexcited precursor. The carbon-free silicon-containing precursor may be essentially nitrogen-free, in some embodiments. However, in other embodiments, both the carbon-free silicon-containing precursor and the radical-nitrogen precursor contain nitrogen. In a third suite of embodiments, the radical precursor may be essentially nitrogen-free and the nitrogen for the carbon-free silicon-nitrogen-and-hydrogen-containing layer may be supplied by the carbon-free silicon-containing precursor. As a result, the radical precursor may be referred to herein as a “radical-nitrogen-and/or-hydrogen precursor,” which means that the precursor contains nitrogen and/or hydrogen. Analogously, the precursor flowed into the plasma region to form the radical-nitrogen-and/or-hydrogen precursor may be referred to as a nitrogen-and/or-hydrogen-containing precursor. This nomenclature may be applied to each of the embodiments disclosed herein. In embodiments, the nitrogen-and/or-hydrogen-containing precursor comprises hydrogen (H₂) while the radical-nitrogen-and/or-hydrogen precursor comprises —H, etc.

Returning to the specific example shown in FIG. 1, the flowability of a silicon-nitrogen-and-hydrogen-containing layer may be due to a variety of properties which result from mixing a radical-nitrogen precursors with a carbon-free silicon-containing precursor. These properties may include a significant hydrogen component in the deposited layer and/or the presence of short chained polysilazane polymers. These short chains grow and network to form more dense dielectric material during and after the formation of the layer. For example the deposited layer may have a silazane-type, Si—NH—Si backbone (i.e., a carbon-free Si—N—H layer). When both the silicon-containing precursor and the radical precursor are carbon-true, the deposited silicon-nitrogen-and-hydrogen-containing layer is also substantially carbon-free. Of course, “carbon-free” does not necessarily mean the layer lacks even trace amounts of carbon. Carbon contaminants may be present in the precursor materials that find their way into the deposited silicon-and-nitrogen-containing precursor. The amount of these carbon impurities however are much less than would be found in a silicon precursor having a carbon moiety (e.g., TEOS, TMDSO, etc.).

At this point in the process, the process effluents may be removed from the substrate processing region in embodiments of the invention. Process effluents may include any unreacted silicon-containing precursor, unreacted radical-nitrogen precursor, inert carrier gases and reaction, products from the layer growth. The process effluents may be displaced by flowing inert species into the substrate processing region and/or by exhaustion through an exhaust port in disclosed embodiments.

The silicon-and-nitrogen-containing layer is then cured and/or annealed in step 108. A curing stage may involve exposing the silicon oxide capping layer and the carbon-free silicon-nitrogen-and-hydrogen-containing layer to an oxygen-containing atmosphere. The oxygen-containing atmosphere may include ozone in embodiments of the invention. The deposition substrate may remain in the substrate processing region for curing, or the substrate may be transferred to a different chamber where the oxygen-containing atmosphere is introduced. The curing temperature of the substrate may be less than or about 300° C., less than or about 250° C., less than or about 225° C., or less than or about 200° C. in different embodiments. The temperature of the substrate may be greater than or about room temperature (25° C.), greater than or about 50° C., greater than or about 100° C., greater than or about 125° C. or greater than or about 150° C. in different embodiments. Any of the upper bounds may be combined with any of the lower bounds to form additional ranges for the substrate temperature according to additional disclosed embodiments.

The curing operation modified the carbon-free silicon-nitrogen-and-hydrogen-containing layer into a silicon-and-oxygen-containing layer. The silicon-and-oxygen-containing layer may be further converted by annealing the substrate at relatively high temperature in an oxygen-containing environment. The deposition substrate may remain in the same substrate processing region used for curing when the oxygen-containing atmosphere is introduced, or the substrate may be transferred to a different chamber where the oxygen-containing atmosphere is introduced. The oxygen-containing atmosphere may include one or more oxygen-containing gases such as molecular oxygen (O₂), ozone (O₃), water vapor (H₂O), hydrogen peroxide (H₂O₂) and nitrogen-oxides (NO, NO₂, etc), among other oxygen-containing gases. The oxygen-containing atmosphere may also include radical oxygen and hydroxyl species such as atomic oxygen (O), hydroxides (OH), etc., that may be generated remotely and transported into the substrate chamber. Ions of oxygen-containing species may also be present. The oxygen-containing atmospheres of the curing and annealing operations provide oxygen to convert the silicon-nitrogen-and-hydrogen-containing layer into a silicon oxide (SiO₂) layer. The oxygen anneal temperature of the substrate may be less than or about 1100° C., less than or about 1000° C., less than or about 900° C. or less than or about 800° C. in different embodiments. The temperature of the substrate may be greater than or about 500° C., greater than or about 600° C., greater than or about 700° C. or greater than or about 800° C. in different embodiments. Once again, any of the upper bounds may be combined with any of the lower bounds to form additional ranges for the substrate temperature according to additional disclosed embodiments.

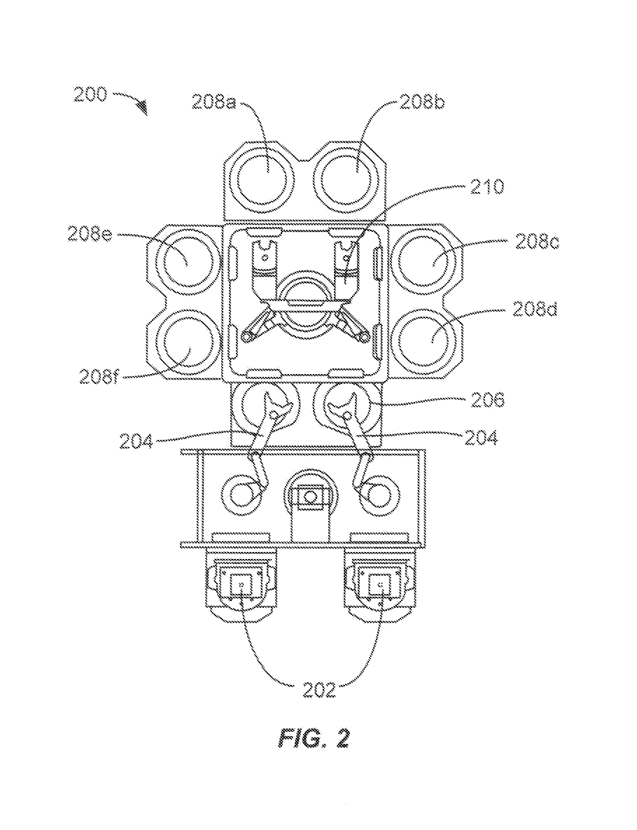

The method 100 also includes a high density plasma treatment of the silicon-and-oxygen-containing layer (operation 110). The HDP treatment would typically require a different style of chamber than that used for the radical-component CVD. The two different chambers may be attached to separate ports on the same substrate processing system as discussed later in conjunction with FIG. 2. It is preferable that the substrate is not exposed to atmosphere between the radical-component deposition, and the HDP treatment in embodiments. The HDP treatment may occur after the curing operation, after an anneal in an oxygen containing environment or after a cure-anneal sequence in embodiments of the invention. Some oxygen ought to be provided before the HDP treatment to the silicon-nitrogen-and-hydrogen-containing layer in one form or another to initiate the conversion to a silicon-and-oxygen-containing layer. In the case of other flowable films, the introduction of oxygen may not be necessary in all embodiments. The impact of ionized species during the HDP treatment results in densification of the treated layer.

A variety of gases may be introduced into the HDP chamber while applying plasma power to excite the gases. The high density plasma may be formed from one or more of O₃, O₂, NH₃, NOₓ, H₂O, H₂, Ar, N₂ or He, in various embodiments of the invention. The ion density and the ionic fraction may be greater than 10¹¹ ions/cm³ and greater than 10⁻⁴, respectively. The deposition-to-sputter ratio may be equal to or approach unity as the scalar quantity is defined herein. The plasma power applied to the high density plasma region will be discussed in more detail in the next section, but may be above or about 1 kW, above or about 3 kW, above or about 5 kW, above or about 7.5 kW, or above or about 10 kW. These plasma powers include or exclude the plasma power applied to bias the substrate relative to the high density plasma in embodiments of the invention.

A high density plasma treatment normally heats a substrate to between about 400° C. and about 450° C. The use of a bias voltage between the substrate and the plasma may increase the substrate temperature further. By flowing a cooling gas behind the substrate or providing another source of substrate cooling, the substrate temperature may be reduced in order to stay within a thermal budget. The temperature of the substrate during HDP treatment may be less than or about 400° C., less than or about 350° C., less than or about 325° C. or less than or about 300° C. in embodiments.

Removing some of the dielectric material prior to the HDP treatment can increase the effectiveness of the treatment allowing further increases in density. This is especially true for gapfill dielectric material. For example, the high density plasma treatment may be preceded by chemical mechanical polishing the dielectric layer to form a new dielectric-air interface positioned closer to the backplane of the patterned substrate. The chemical mechanical polishing step occurs after depositing the dielectric layer and may occur after the curing operation and after the annealing operation, in various embodiments of the invention. The HDP treatment is possibly causing collisions between gas phase ions and molecular fragments with the new dielectric-air interface during the HDP treatment. The collisions are occurring nearer the gapfill portion of the dielectric layer which enables a greater magnitude of densification compared to processing which omits the CMP step. Similarly, the density may be increased by separating a deposition into multiple deposition-densification sequences. In embodiments, the sequential steps are repeated at least twice to increase a dielectric density compared with a single deposition sequence of the same total thickness.

A high density plasma treatment normally heats a substrate to between about 400° C. and about 450° C. The use of a bias voltage between the substrate and the plasma may increase the substrate temperature further. By flowing a cooling gas behind the substrate or providing another source of substrate cooling, the substrate temperature may be reduced in order to stay within a thermal budget. The temperature of the substrate during HDP treatment may be less than or about 400° C., less than or about 350° C., less than or about 325° C., or less than or about 300° C. in embodiments.

The substrate used for depositing the carbon-free silicon-nitrogen-and-hydrogen-containing layer and the capping layer may be a patterned substrate and may have a plurality of gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., less than 90 nm, 65 nm, 50 nm, 45 nm, 32 nm, 22 nm, 16 nm, etc.). Because the carbon-free silicon-nitrogen-and-hydrogen-containing layer is flowable, it can fill gaps with high aspect ratios without creating voids or weak seams around the center of the filling material. For example, a depositing flowable material is less likely to prematurely clog the top of a gap before it is completely filled to leave a void in the middle of the gap.

Additional process parameters may be introduced in the course of describing an exemplary silicon oxide deposition system.

### Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Embodiments of the deposition systems may be incorporated into larger fabrication systems for producing integrated circuit chips. FIG. 2 shows one such system 200 of deposition, baking and curing chambers according to disclosed embodiments. In the figure, a pair of FOUPs (from opening unified pods) 202 supply substrate substrates (e.g., 300 mm diameter wafers) that are received by robotic arms 204 and placed into a low pressure holding area 206 before being placed into one of the substrate processing chambers 208a-f. A second robotic arm 210 may be used to transport the substrate wafers from the low pressure holding area 206 to the substrate processing chambers 208a-f and back.

Substrate processing chambers 208a-f may include one or more system components for depositing, annealing, curing and/or etching a flowable dielectric layer on the substrate water. In one configuration, two pairs of the processing chamber (e.g., 208c-d and 208e-f) may be used to deposit the flowable dielectric material on the substrate, and the third pair of processing chambers (e.g., 208a-b) may be used to anneal the deposited dielectric. In another configuration, the same two pairs of processing chambers (e.g., 208c-d and 208e-f may be configured to both deposit and anneal a flowable dielectric layer on the substrate, while the third pair of chambers (e.g., 208a-b) may be used for UV or E-beam curing of the deposited layer. In still another configuration, all three pairs of chambers (e.g., 208a-f) may be configured to deposit and cure a flowable dielectric layer on the substrate. In yet another configuration, two pairs of processing chambers (e.g., 208c-d and 208e-f) may be used for both deposition and UV or E-beam curing of the flowable dielectric, while a third pair of processing chambers (e.g. 208a-b) may be used for annealing the dielectric layer. Any one or more of the processes described may be carried out on chamber(s) separated from the fabrication system shown in different embodiments.

In addition, one or more of the substrate processing chambers 208a-f may be configured as a wet treatment chamber. These process chambers include heating the flowable dielectric layer in an atmosphere that includes moisture. Thus, embodiments of system 200 may include wet treatment chambers and anneal processing chambers to perform both wet and dry anneals on the deposited dielectric layer.

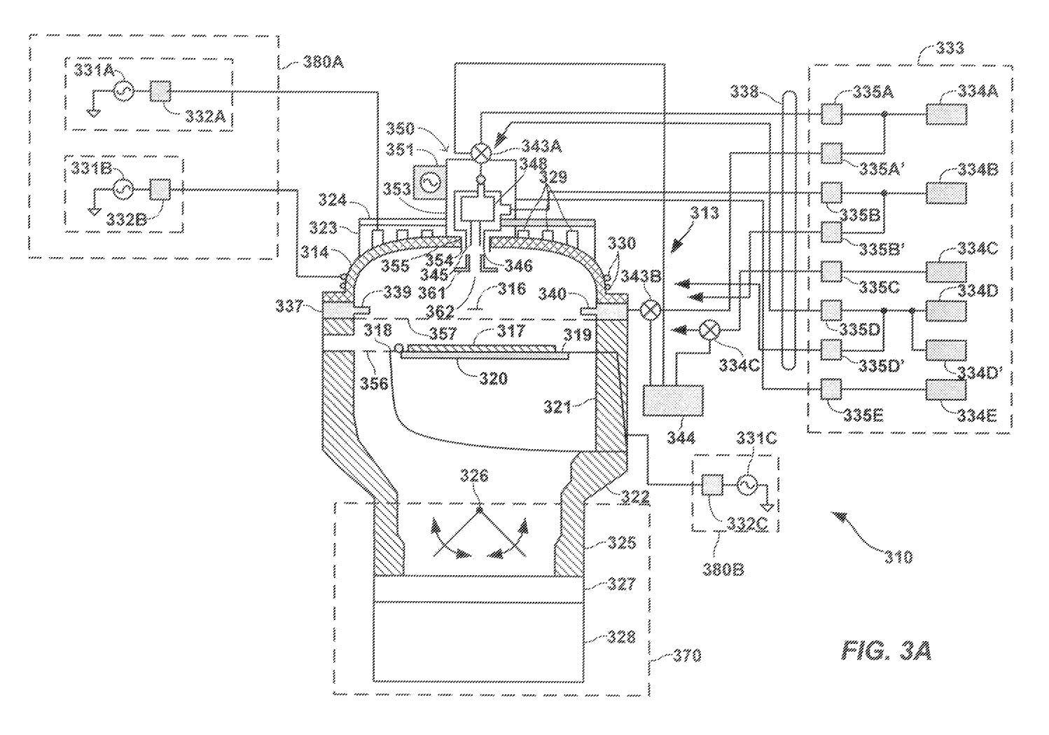

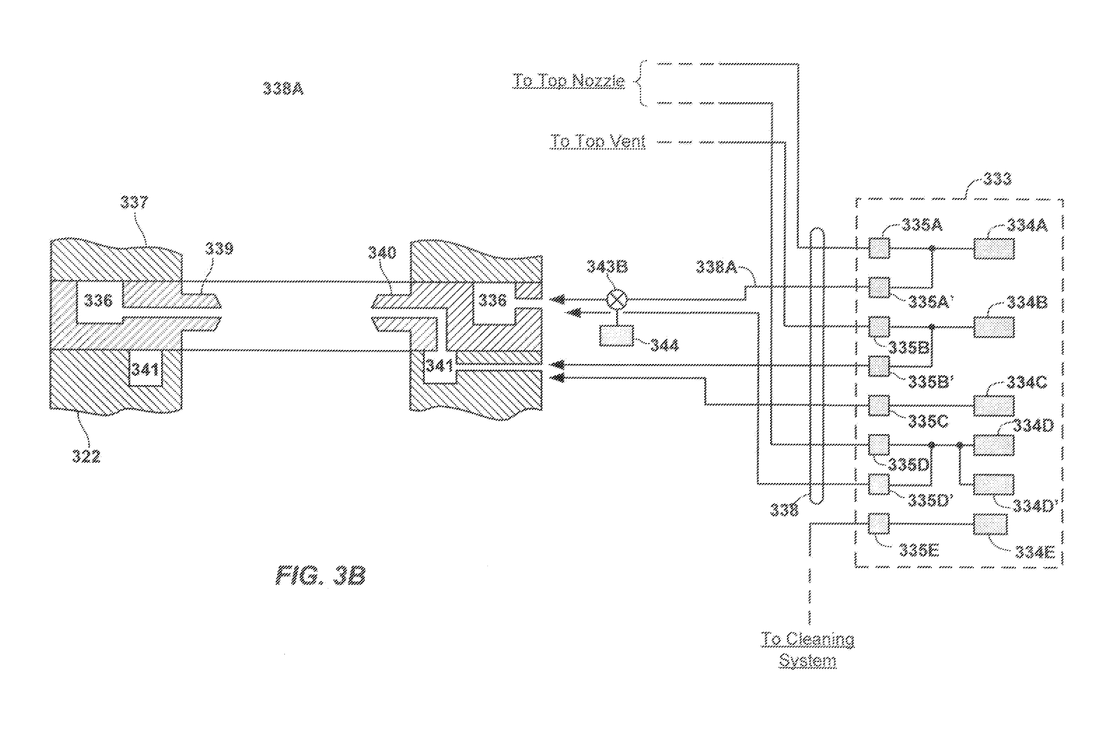

The inventors have implemented embodiments of the invention with the ULTIMA® system manufactured by APPLIED MATERIALS, INC., of Santa Clara, Calif., a general description of which is provided in commonly assigned U.S. Pat. No. 6,170,428, “SYMMETRIC TUNABLE INDUCTIVELY COUPLED HDP-CVD REACTOR,” filed Jul. 15, 1996 by Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha, the entire disclosure of which is incorporated herein by reference. An overview of the system is provided in connection with FIGS. 3A and 3B below. FIG. 3A schematically illustrates the structure of such an HDP-CVD system 310 in an embodiment. The system 310 includes a chamber 313, a vacuum system 370, a source plasma system 380A, a substrate bias plasma system 380B, a gas delivery system 333, and a remote plasma cleaning system 350.

The upper portion of chamber 313 includes a dome 314, which is made of a ceramic dielectric material, such as aluminum oxide or aluminum nitride. Dome 314 defines an upper boundary of a plasma processing region 316. Plasma processing region 316 is bounded on the bottom by the upper surface of a substrate 317 and a substrate support member 318.

A heater plate 323 and a cold plate 324 surmount, and are thermally coupled to, dome 314. Heater plate 323 and cold plate 324 allow control of the dome temperature to within about +10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 313 includes a body member 322, which joins the chamber to the vacuum system. A base portion 321 of substrate support member 318 is mounted on, and forms a continuous inner surface with, body member 322. Substrates are transferred into and out of chamber 313 by a robot blade (not shown) through an insertion/removal opening (not shown) in the side of chamber 313. Lift pins (not shown) are raised and then lowered under the control of a motor (also not shown) to move the substrate from the robot blade at an upper loading position 357 to a lower processing position 356 in which the substrate is placed on a substrate receiving portion 319 of substrate support member 318. Substrate receiving portion 319 includes an electrostatic chuck 320 that secures the substrate to substrate support member 318 during substrate processing. In a preferred embodiment, substrate support member 318 is made from an aluminum oxide or aluminum ceramic material.

Vacuum system 370 includes throttle body 325, which houses twin-blade throttle valve 326 and is attached to gate valve 327 and turbo-molecular pump 328. It should be noted that throttle body 325 offers minimum obstruction to gas flow, and allows symmetric pumping. Gate valve 327 can isolate pump 328 from throttle body 325, and can also control chamber pressure by restricting the exhaust flow capacity when throttle valve 326 is fully open. The arrangement of the throttle valve, gate valve, and turbo-molecular pump allow accurate and stable control of chamber pressures up to about 1 mTorr to about 2 Torr.

The source plasma system 380A includes a top coil 329 and side coil 330, mounted on dome 314. A symmetrical ground shield (not shown) reduces electrical coupling between the coils. Top coil 329 is powered by top source RF (SRF) generator 331A, whereas side coil 330 is powered by side SRF generator 331B, allowing independent power levels and frequencies of operation for each coil. This dual coil system allows control of the radial ion density in chamber 313, thereby improving plasma uniformity. Side coil 330 and top coil 329 are typically inductively driven, which does not require a complimentary electrode. In a specific embodiment, the top source RF generator 331A provides up to 5,000 watts of RF power at nominally 2 MHz and the side source RF generator 331B provides up to 7,500 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A substrate bias plasma system 380B includes a bias RF (“BRF”) generator 331C and a bias matching network 332C. The bias plasma system 380B capacitively couples substrate portion 317 to body member 322, which act as complimentary electrodes. The bias plasma system 380B serves to enhance the transport of plasma species (e.g., ions) created by the source plasma system 380A to the surface of the substrate. In a specific embodiment, the substrate bias RF generator provides up to 10,000 watts of RF power at a frequency of about 13.56 MHz. The high density plasma may be formed by applying an RF power greater than or about 1 kW, greater than or about 1.5 kW or greater than or about 2 kW in embodiments. The RF power tor forming the high density plasma includes power from the source plasma system (e.g. 380A) and may also include power from a substrate bias plasma system (e.g. 380B) in embodiments of the invention.

RF generators 331A and 331B include digitally controlled synthesizers. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 332A and 332B match the output impedance of generators 331A and 331B with their respective coils 329 and 330. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 333 provides gases from several sources, 334A-334E to a chamber for processing the substrate by way of gas delivery lines 338 (only some of which are shown). As would be understood by a person of skill in the art, the actual sources used for sources 334A-334E and the actual connection of delivery lines 338 to chamber 313 varies depending on the deposition and cleaning processes executed within chamber 313. Gases are introduced into chamber 313 through a gas ring 337 and/or a top nozzle 345. FIG. 3B is a simplified, partial cross-sectional view of chamber 313 showing additional details of gas ring 337.

In one embodiment, first and second gas sources, 334A and 334B, and first and second gas flow controllers, 335A′ and 335B′, provide gas to ring plenum 336 in gas ring 337 by way of gas delivery lines 338 (only some of which are shown). Gas ring 337 has a plurality of source gas nozzles 339 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 337 has 12 source gas nozzles made from an aluminum oxide ceramic.

Gas ring 337 also has a plurality of oxidizer gas nozzles 340 (only one of which is shown), which in one embodiment are co-planar with and shorter than source gas nozzles 339, and in one embodiment receive gas from body plenum 341. In some embodiments it is desirable not to mix source gases and oxidizer gases before injecting the gases into chamber 313. In other embodiments, oxidizer gas and source gas may be mixed prior to injecting the gases into chamber 313 by providing apertures (not shown) between body plenum 341 and gas ring plenum 336. In one embodiment, third, fourth, and fifth gas sources, 334C, 334D, and 334D′, and third and fourth gas flow controllers, 335C and 335D′, provide gas to body plenum by way of gas delivery lines 338. Additional valves, such as 343B (other valves not shown), may shut off gas from the flow controllers to the chamber. In implementing certain embodiments of the invention, source 334A comprises a silane SiH₄ source, source 334B comprises a molecular nitrogen N₂ source, source 334C comprises a TSA source, source 334D comprises an argon Ar source, and source 334D′ comprises a disilane Si₂H₆ source.

In embodiments where flammable, toxic, or corrosive gases are used, if may be desirable to eliminate gas remaining in the gas delivery lines after a deposition. This may be accomplished using a 3-way valve, such as valve 343B, to isolate chamber 313 from delivery line 338A and to vent delivery line 338A to vacuum foreline 344, for example. As shown in FIG. 3A, other similar valves, such, as 343A and 343C, may be incorporated on other gas delivery lines. Such three-way valves may be placed as close to chamber 313 as practical, to minimize the volume of the unvented gas delivery line (between the three-way valve and the chamber). Additionally, two-way (on-off) valves (not shown) may be placed between a mass flow controller (“MFC”) and the chamber or between a gas source and an MFC.

Referring again to FIG. 3A, chamber 313 also has top nozzle 345 and top vent 346. Top nozzle 345 and top vent 346 allow independent control of top and side flows of the gases, which improves film uniformity and allows fine adjustment of the film's deposition and doping parameters. Top vent 346 is an annular opening around top nozzle 345. In one embodiment, first gas source 334A supplies source gas nozzles 339 and top nozzle 345. Source nozzle MFC 335A′ controls the amount of gas delivered to source gas nozzles 339 and top nozzle MFC 335A controls the amount of gas delivered to top gas nozzle 345. Similarly, two MFCs 335B and 335B′ may be used to control the flow of oxygen to both top vent 346 and oxidizer gas nozzles 340 from a single source of oxygen, such as source 334B. In some embodiments, oxygen is not supplied to the chamber from any side nozzles. The gases supplied to top nozzle 345 and top vent 346 may be kept separate prior to blowing the gases into chamber 313, or the gases may be mixed in top plenum 348 before they flow into chamber 313. Separate sources of the same gas may be used to supply various portions of the chamber.

A remote microwave-generated plasma cleaning system 350 is provided to periodically clean deposition residues from chamber components. The cleaning system includes a remote microwave generator 351 that creates a plasma from a cleaning gas source 334E (e.g., molecular fluorine, nitrogen trifluoride, other fluorocarbons or equivalents) in reactor cavity 353. The reactive species resulting from this plasma are conveyed to chamber 313 through cleaning gas feed port 354 by way of applicator tube 355. The materials used to contain the cleaning plasma (e.g., cavity 353 and applicator tube 355) must be resistant to attack by the plasma. The distance between reactor cavity 353 and feed pen 354 should be kept as short as practical, since the concentration of desirable plasma species may decline with distance from reactor cavity 353. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 320, do not need to be covered with a dummy wafer or otherwise protected, as may be required with an in situ plasma cleaning process. In FIG. 3A, the plasma-cleaning system 350 is shown disposed above the chamber 313, although other positions may alternatively be used.

A baffle 361 may be provided proximate the top nozzle to direct flows of source gases supplied through the ton nozzle into the chamber and to direct flows of remotely generated plasma. Source gases provided through top nozzle 345 are directed through a central passage 362 into the chamber, while remotely generated plasma species provided through the cleaning gas feed port 354 are directed to the sides of the chamber by the baffle 361.

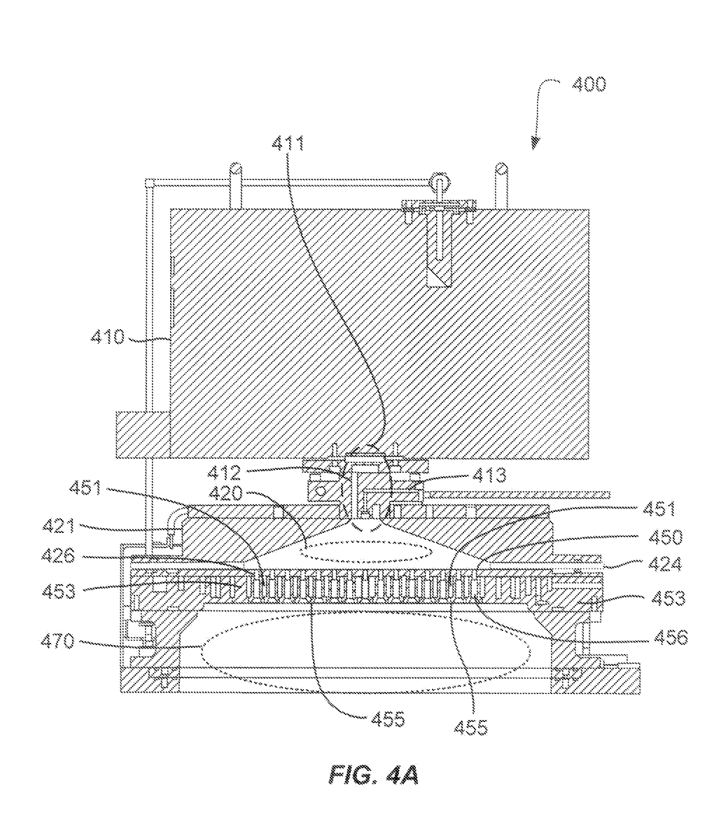

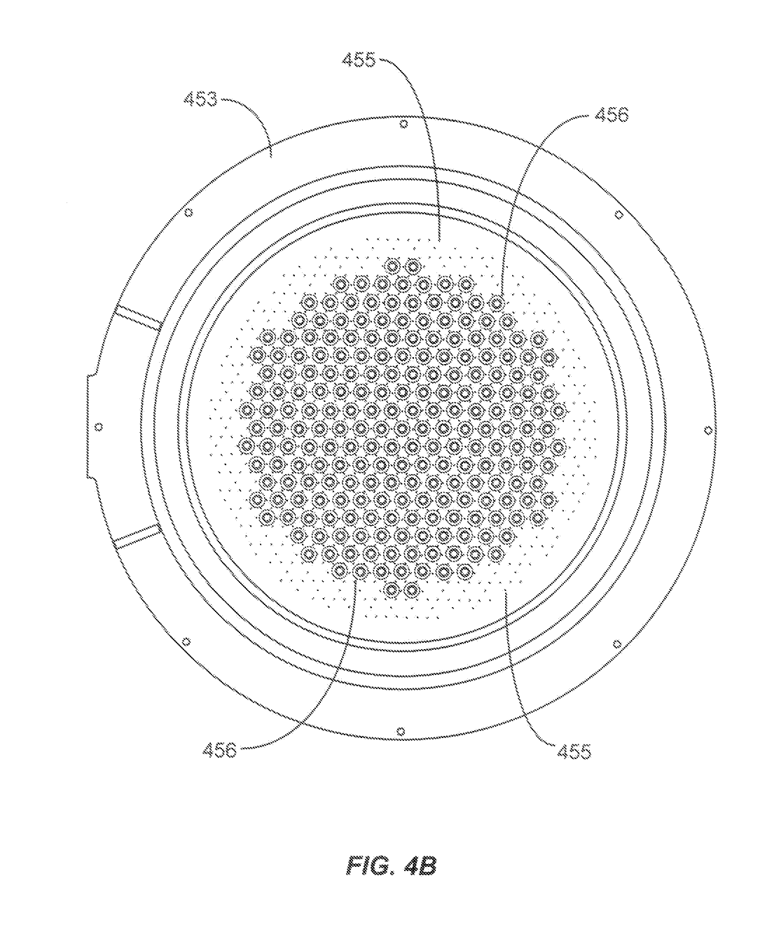

FIG. 4A is a substrate processing chamber 400 according to disclosed embodiments. A remote plasma system (RPS) 410 may process a gas which then travels through a gas inlet assembly 411. Two distinct gas supply channels are visible within the gas inlet assembly 411. A first channel 412 carries a gas that passes through the remote plasma system (RPS) 410, while a second channel 413 bypasses the RPS 410. The first channel 412 may be used for the process gas and the second channel 413 may be used tor a treatment gas in disclosed embodiments. The lid (or conductive top portion) 421 and a perforated partition or showerhead 453 are shown with an insulating ring 424 in between, which allows an AC potential to be applied to the lid 421 relative to showerhead 453. The process gas travels through first channel 412 into chamber plasma region 420 and may be excited by a plasma in chamber plasma region 420 alone or in combination with RPS 410. The combination of chamber plasma region 420 and/or RPS 410 may be referred to as a remote plasma system herein. The perforated partition (also referred to as a showerhead) 453 separates chamber plasma region 420 from a substrate processing region 470 beneath showerhead 453. Showerhead 453 allows a plasma present in chamber plasma region 420 to avoid directly exciting gases in substrate processing region 470, while still allowing excited species to travel from chamber plasma region 420 into substrate processing region 470.

Showerhead 453 is positioned between chamber plasma region 420 and substrate processing region 470 and allows plasma effluents (excited derivatives of precursors or other gases) created within chamber plasma region 420 to pass through a plurality of through-holes 456 that traverse the thickness of the plate. The showerhead 453 also has one or more hollow volumes 451 which can be filled with a precursor in the form of a vapor or gas (such as a silicon-containing precursor) and pass through small holes 455 into substrate processing region 470 but not directly into chamber plasma region 420. Showerhead 453 is thicker than the length of the smallest diameter 450 of the through-holes 456 in this disclosed embodiment. In order to maintain a significant concentration of excited species penetrating from chamber plasma region 420 to substrate processing region 470, the length 426 of the smallest diameter 450 of the through-holes may be restricted by forming larger diameter portions of through-holes 456 part way through the showerhead 453. The length of the smallest diameter 450 of the through-boles 456 may be the same order of magnitude as the smallest diameter of the through-holes 456 or less in disclosed embodiments.

In the embodiment shown, showerhead 453 may distribute (via through-holes 456) process gases which contain oxygen, hydrogen and/or nitrogen and/or plasma effluents of such process gases upon excitation by a plasma in chamber plasma region 420. In embodiments, the process gas introduced into the RPS 410 and/or chamber plasma region 420 through first channel 412 may contain one or more of oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 413 may also deliver a process gas and/or a carrier gas, and/or a layer-curing gas (e.g. O₃ used to remove an unwanted component from the growing or as-deposited layer. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 456 may be between about 60 and about 2000. Through-holes 456 may have a variety of shapes but are most easily made round. The smallest diameter 450 of through-holes 456 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 455 used to introduce a gas into substrate processing region 470 may be between about 100 and about 5000 or between about 500 and about 2000 in different embodiments. The diameter of the small holes 455 may be between about 0.1 mm and about 2 mm.

FIG. 4B is a bottom view of a showerhead 453 for use with a processing chamber according to disclosed embodiments. Showerhead 453 corresponds with the showerhead shown in FIG. 3A. Through-holes 456 are depicted with a larger inner-diameter (ID) on the bottom of showerhead 453 and a smaller ID at the top. Small holes 455 are distributed substantially evenly over the surface of the showerhead, even amongst the through-boles 456 which helps to provide more even mixing than other embodiments described herein.

An exemplary layer is created on a substrate supported by a pedestal (not shown) within substrate processing region 470 when plasma effluents arriving through through-holes 456 in showerhead 453 combine with a silicon-containing precursor arriving through the small holes 455 originating from hollow volumes 451. Though substrate processing region 470 may be equipped to support a plasma for other processes such as curing, no plasma is present during the growth of the exemplary layer.

A plasma may be ignited either in chamber plasma region 420 above showerhead 453 or substrate processing region 470 below showerhead 453. A plasma is present in chamber plasma region 420 to produce the radical nitrogen precursor from an inflow of a nitrogen-and-hydrogen-containing gas. An AC voltage typically in the radio frequency (RF) range is applied between the conductive top portion formed in lid 421 of the processing chamber and showerhead 453 to ignite a plasma in chamber plasma region 420 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 470 is turned on during the second curing stage or clean the interior surfaces bordering substrate processing region 470. A plasma in substrate processing region 470 is ignited by applying an AC voltage between showerhead 453 and the pedestal or bottom of the chamber. A cleaning gas may be introduced into substrate processing region 470 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded, heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller, in an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the deposition system. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a layer stack (e.g. sequential deposition of a carbon-free silicon-nitrogen-and-hydrogen-containing layer and then a silicon oxide capping layer) on a substrate, converting a layer to silicon oxide or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” may include minority concentrations of other elemental constituents such as nitrogen, hydrogen, carbon and the like. In some embodiments, silicon oxide consists essentially of silicon and oxygen. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas (or precursor) may be a combination of two or more gases (or precursors). A “radical precursor” is used to describe plasma effluents (a gas in an excited state which is exiting a plasma) which participate in a reaction to either remove material from or deposit material on a surface. A “radical-nitrogen precursor” is a radical precursor which contains nitrogen and a “radical-hydrogen precursor” is a radical precursor which contains hydrogen. The phrase “inert gas” refers to any gas which does not form chemical bonds when etching or being incorporated into a layer. Exemplary inert gases include noble gases but may include other gases so long as no chemical bonds are formed when (typically) trace amounts are trapped in a layer.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which, may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of forming a dielectric layer on a substrate, the method comprising the sequential steps of:
forming a dielectric layer on the substrate, wherein the dielectric layer is flowable during the operation of forming the dielectric layer, and
treating the dielectric layer by exposing the layer to a high density plasma, wherein exposing the layer to the high density plasma increases a density of the dielectric layer.

2. The method of claim 1 wherein a temperature of the substrate is maintained below 400° C. during the operation of treating the dielectric layer.

3. The method of claim 1 wherein a plasma density of the high density plasma is on the order of 10¹¹ ions/cm³ or greater.

4. The method of claim 1 wherein the high density plasma is formed from one or more of O₃, O₂, NH₃, NOₓ, H₂O, H₂, Ar, N₂ or He.

5. The method of claim 1 wherein the high density plasma is formed by applying an RF power greater than or about 1 kW.

6. The method of claim 1 wherein a vertical thickness of the dielectric layer remains the same or decreases and essentially no new layer is formed above the dielectric layer during the operation of treating the dielectric layer with the high density plasma.

7. The method of claim 1 wherein a step of chemical mechanical polishing occurs after forming the dielectric layer and before treating the dielectric layer to increase its density.

8. The method of claim 1 wherein the sequential steps are repeated at least twice to increase a dielectric density compared with a single deposition sequence of the same total thickness.

9. The method of claim 1 wherein forming the dielectric layer comprises forming a layer comprising silicon, carbon, oxygen, hydrogen and nitrogen.

10. The method of claim 1 wherein forming the dielectric layer comprises forming a layer comprising silicon, nitrogen and hydrogen.

11. The method of claim 1 wherein the dielectric layer is essentially carbon-free.

12. The method of claim 1 wherein forming the dielectric layer comprises forming the dielectric layer by chemical vapor deposition (CVD).

13. The method of claim 12 wherein the dielectric layer is formed by radical-component CVD.

14. The method of claim 1 wherein forming the dielectric layer comprises forming a spin-on glass (SOG) or spin-on dielectric (SOD) layer.

15. The method of claim 1 wherein forming the dielectric layer comprises forming a sub-atmospheric chemical vapor deposition (SACVD) layer.

16. The method of claim 15 wherein forming the SACVD layer comprises combining O₃, TEOS and H₂O in the absence of a plasma.
